(19) United States
(12) Patent Application Publication
(10) Pub. No.: US 2010/0134668 A1
(43) Pub. Date: Jun. 3, 2010

(54) Image sensors

(75) Inventors: Jong Eun Park, Seongnam-si (KR); Yong Jei Lee, Seongnam-si (KR); Jung Chak Ahn, Yongin-si (KR); Dong-Yoon Jang, Hwasung-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/591,721

(22) Filed: Nov. 30, 2009

(30) Foreign Application Priority Data
Dec. 1, 2008 (KR) 10-2008-0120532
Dec. 1, 2008 (KR) 10-2008-0120534

(51) Int. Cl. H04N 5/335; H01L 31/0352

(52) U.S. Cl. 348/294; 257/447; 348/E05.091; 257/E31.032; 257/E31.11

(57) ABSTRACT

An image sensor includes a plurality of wells for isolating a plurality of photodiodes from each other. Each of the wells includes a P-type well region and an N-type well region configured to receive a positive bias voltage. The image sensor provides a clearer image by suppressing a blooming effect and a dark current.

### CROSS-REFERENCE TO RELATED APPLICATION(S)

This application claims priority under 35 U.S.C. §119 to Korean Patent Application Nos. 10-2008-0120532 filed on Dec. 1, 2008, 10-2008-0120534 filed on Dec. 1, 2008, in the Korean Intellectual Property Office, the entire contents of which are incorporated herein by reference.

### BACKGROUND

1. Field

Example embodiments of inventive concepts relate to image sensors, for example, back-side illumination (BSI) image sensors capable of suppressing dark currents on a silicon surface above a photodiode.

2. Description of Conventional Art

Image sensors are usually classified as charge-coupled device (CCD) image sensors and complementary metal-oxide semiconductor (CMOS) image sensors (CISs). Image sensors include a plurality of pixels arranged in a two-dimensional matrix. Each pixel outputs an image signal in response to incident light energy. In more detail, each pixel accumulates photo-generated charges corresponding to the quantity of light input through a photodiode and outputs a pixel signal based on the accumulated charge.

In an image sensor, pixels are usually isolated from each other by a P-type well formed between the pixels. The P-type well has a higher potential barrier than a photodiode. However, electrons excessively generated at the photodiode by relatively strong light may overflow the potential barrier of the P-type well and act as noise to an adjacent photodiode. This phenomenon is referred to as a blooming effect. Moreover, as the operating temperature of an image sensor increases, electrons generated at a P-type well may act as noise to a photodiode. A current generated by such electrons is referred to as a dark current.

### SUMMARY

Example embodiments of inventive concepts provide image sensors for generating a pixel signal that provides a clearer image by suppressing a blooming effect and a dark current. Example embodiments also provide electronic systems including image sensors.

At least one example embodiment provides an image sensor. The image sensor includes: a plurality of photodiodes and a plurality of wells configured to isolate the plurality of photodiodes from each other. Each of the plurality of wells includes a P-type well region and an N-type well region formed within the P-type well region.

At least one other example embodiment provides an electronic system. The electronic system includes: an image sensor, a memory and a processor. The image sensor is configured to generate an image. The memory is configured to store the generated image. The processor is coupled to the memory and the image sensor via a bus. The processor is configured to control the image sensor and the memory. According to at least this example embodiment, the image sensor includes: a plurality of photodiodes and a plurality of wells configured to isolate the plurality of photodiodes from each other. Each of the plurality of wells includes: a P-type well region and an N-type well region formed within the P-type well region.

According to at least some example embodiments, a positive voltage may be applied to the N-type well region. The positive voltage may have a voltage level that varies according to the operating state of the image sensor. The image sensor may further include an oxide layer formed above each of the plurality of wells. The oxide layer may be formed within a trench. The trench may be formed using a shallow trench insulation (STI) process. The image sensor may further include an N-type substrate electrically connected to the N-type well region. The plurality of photodiodes may be formed between a first P-type layer and a second P-type layer.

### BRIEF DESCRIPTION OF THE DRAWINGS

Inventive concepts will become more apparent by describing in detail example embodiments thereof with reference to the attached drawings in which:

FIG. 1 is a layout of a pixel array included in an image sensor according to an example embodiment;

FIG. 2 is a sectional view of the pixel array illustrated in FIG. 1 according to an example embodiment;

FIG. 3 is a graph illustrating a potential barrier with respect to a partial cross-section of the pixel array illustrated in FIG. 2;

FIG. 4 illustrates a cross-section of a well illustrated in FIG. 2;

FIGS. 5A through 5C are schematic layouts of a pixel in a pixel array included in an image sensor according to an example embodiment;

FIG. 6 is a sectional view of a pixel array included in an image sensor according to another example embodiment;

FIG. 7 is a circuit diagram of a unit pixel included in an image sensor according to an example embodiment;

FIG. 8 is a block diagram of an image sensor according to example embodiment; and

FIG. 9 is a block diagram of an electronic system including an image sensor according to an example embodiment.

### DETAILED DESCRIPTION

Inventive concepts will now be described more fully hereinafter with reference to the accompanying drawings, in which example embodiments are shown. Inventive concepts may, however, be embodied in many different forms and should not be construed as limited to the example embodiments set forth herein. Rather, these example embodiments are provided so that this disclosure will be thorough and complete, and will fully convey the scope of inventive concepts to those skilled in the art. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first signal could be termed a second signal, and, similarly, a second signal could be termed a first signal without departing from the teachings of the disclosure.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

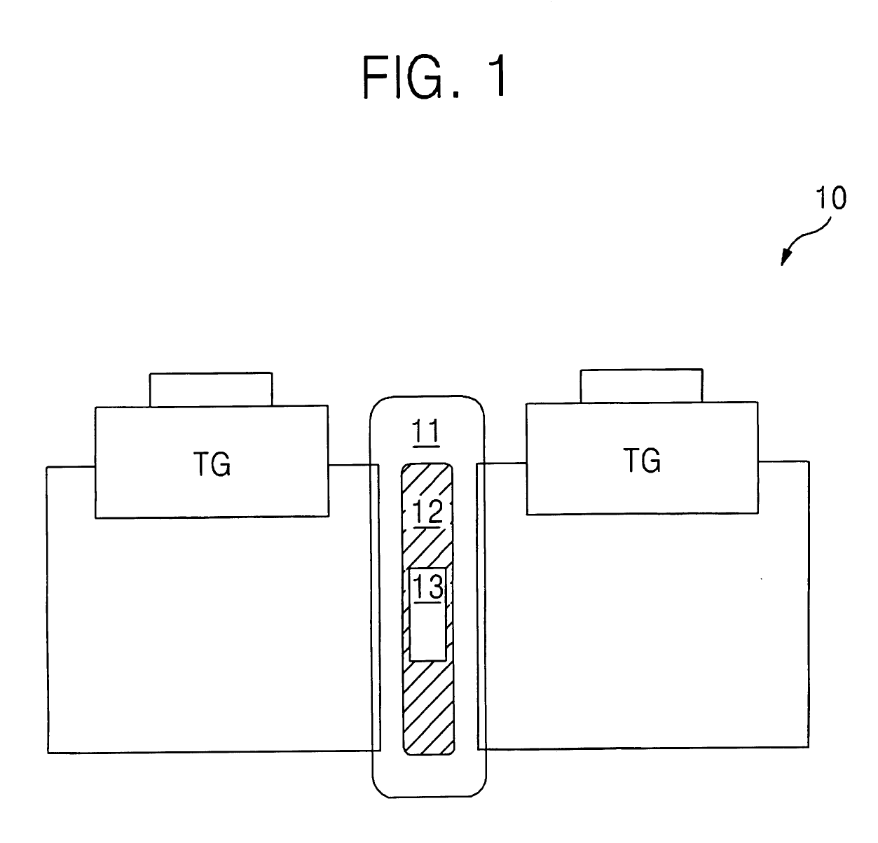

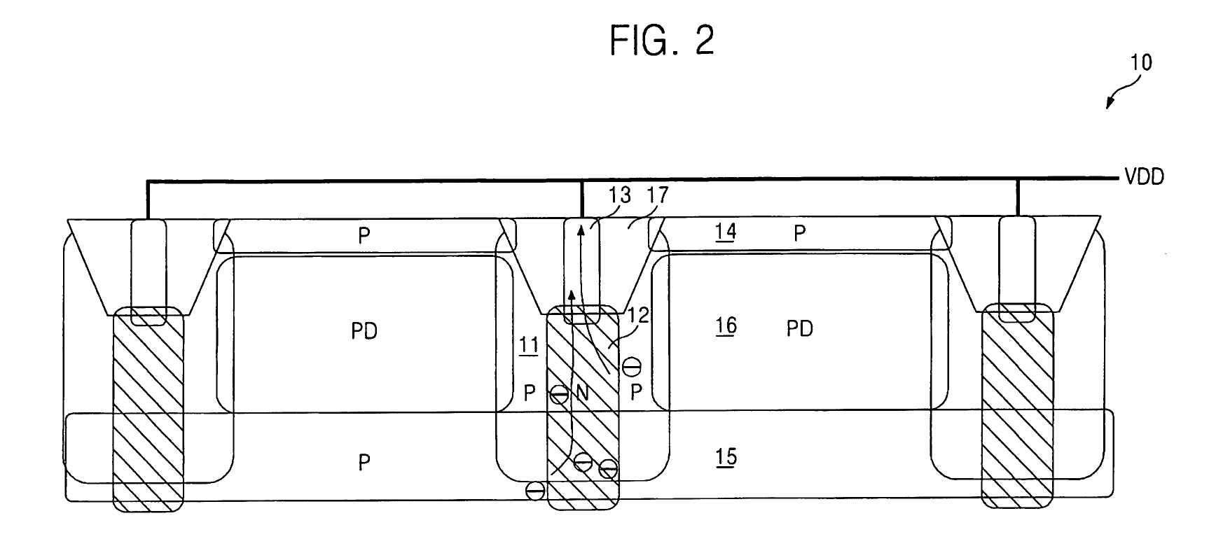

FIG. 1 is a layout of a pixel array 10 included in an image sensor according to an example embodiment. FIG. 2 is a sectional view of the pixel array 10 illustrated in FIG. 1 according to an example embodiment.

Referring to FIGS. 1 and 2, a unit pixel of the pixel array 10 includes a gate TG of a transfer transistor (not shown), a P-type well region 11, an N-type well region 12, a contact 13, a first P-type layer 14, a second P-type layer 15, a photodiode (PD) 16, and a shallow trench insulation (STI) structure.

FIG. 1 illustrates the pixel array 10 viewed from above, and thus, shows only the gate TG of the transfer transistor, the P-type well region 11, the N-type well region 12, and the contact 13 formed on a silicon substrate. The image sensor illustrated in FIGS. 1 and 2 is a back-side illumination (BSI) image sensor, which includes the first P-type layer 14 and the PD 16 formed on the second P-type layer 15. Hereinafter, the image sensor is a BSI image sensor, but inventive concepts are not restricted thereto.

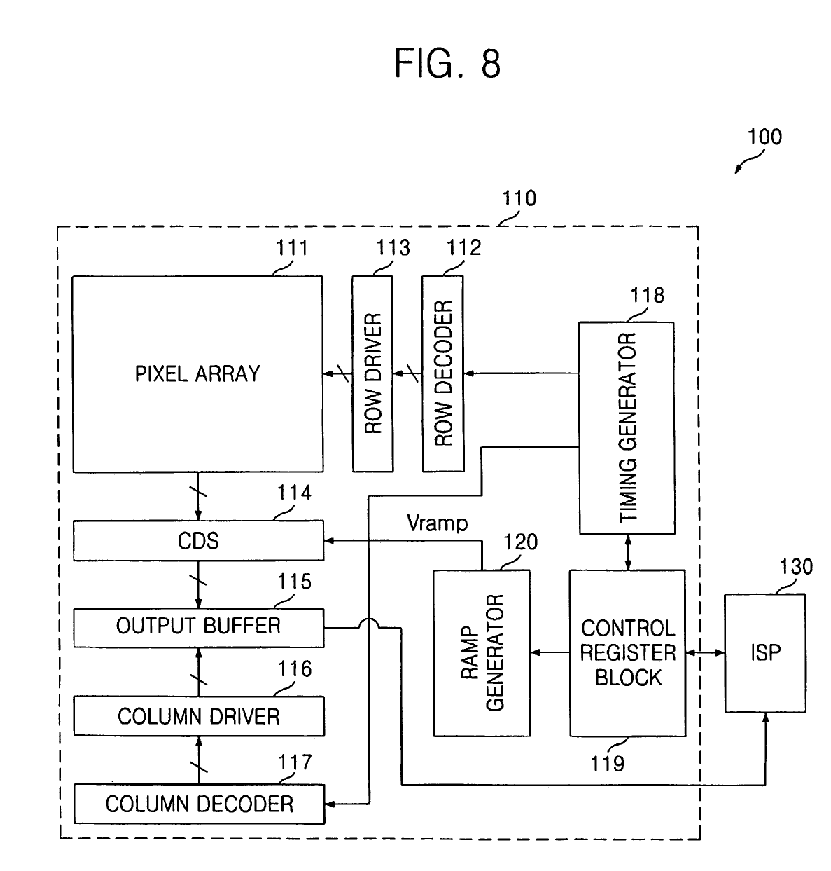

The transfer transistor outputs electrons accumulated at the PD 16 to a floating diffusion region (not shown) in response to a transfer signal applied to the gate TG. The operation of a unit pixel of the pixel array 10 will be described in more detail later with reference to FIG. 8.

The P-type well region 11 electrically isolates the PDs from each other. In more detail, for example, the P-type well region 11 has a higher potential barrier than the PDs, and thus, the P-type well region 11 suppresses and/or prevents electrons generated at the PD 16 from over flowing to an adjacent PD.

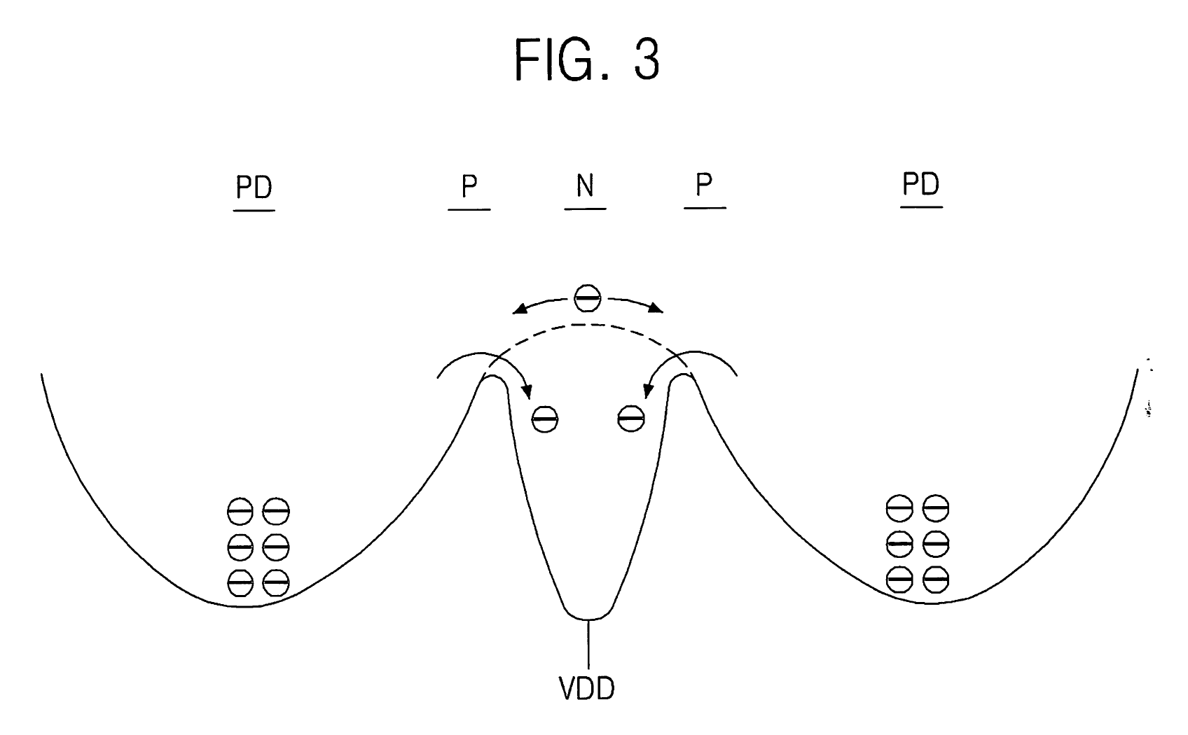

The N-type well region 12 is formed within the P-type well region 11 and receives a positive voltage VDD. The level of the positive voltage VDD varies with an operating state of the image sensor. The N-type well region 12 is connected to a voltage line supplying the positive voltage VDD through the contact 13. When the positive voltage VDD is applied to the N-type well region 12, a blooming effect is suppressed. A blooming effect occurs when electrons excessively generated by strong light affect the adjacent PD. The manner in which the blooming effect is suppressed will be described in more detail below with reference to FIG. 3.

FIG. 3 is a graph illustrating a potential barrier with respect to a partial cross-section of the pixel array 10 illustrated in FIG. 2.

Referring to FIG. 3, electrons are accumulated at the PD 16 surrounded by the P-type well region 11 having a relatively high potential barrier. Even when electrons excessively generated at the PD 16 overflow the P-type well region 11, the electrons are drained by the positive voltage VDD applied to the N-type well region 12 formed within the P-type well region 11, and thus, their effect on the adjacent PD is suppressed and/or prevented.

The level of the positive voltage VDD may be changed based on the operating state of the image sensor. For example, the level of the positive voltage VDD may be changed based on a noise signal generated from a dark image. The level of the positive voltage VDD may be increased as the noise signal increases. Noise suppression and/or elimination performance increases when the level of the positive voltage VDD increases, but the level of the positive voltage VDD may be varied within a range in which the potential barrier of the P-type well region 11 may be maintained.

If the N-type well region 12 does not exist, the P-type well region 11 has a potential barrier denoted by a dotted line. In this case, electrons excessively generated at the PD 16 are not drained, but overflow the potential barrier of the P-type well region 11, thereby affecting the adjacent PD.

The N-type well region 12 also suppresses a dark current that occurs when electrons generated at the second P-type layer 15 flow into the PD 16. In more detail, a minority carrier electron generated at the second P-type layer 15 based on light input through the PD 16, the increase of operating temperature, and so on may be drained to the N-type well region 12.

As described above, due to the suppression of the blooming effect and the dark current by the N-type well region 12, the image sensor may provide a clearer and/or sharper image signal.

The first P-type layer 14 drains electrons generated at a silicon surface above the PD 16, thereby suppressing a dark current. The second P-type layer 15 is formed below the PD 16. The height of a potential barrier may be controlled in a vertical direction of the pixel, for example, along the first P-type layer 14, the PD 16, and/or the second P-type layer 15 by adjusting the concentration of the first P-type layer 14, the second P-type layer 15, and/or the PD 16.

An oxide layer 17 is formed above the P-type well region 11 and the N-type well region 12, thereby isolating the PD 16 from the adjacent PD. The oxide layer 17 may be formed within a trench. The trench may be formed using an STI process. The STI process is known, and thus, a detailed description thereof will be omitted.

If the pixel array 10 is formed on an N-type substrate (not shown), the N-type well region 12 may be electrically connected with the N-type substrate and the positive voltage VDD may be commonly applied to the N-type well region 12 and the N-type substrate.

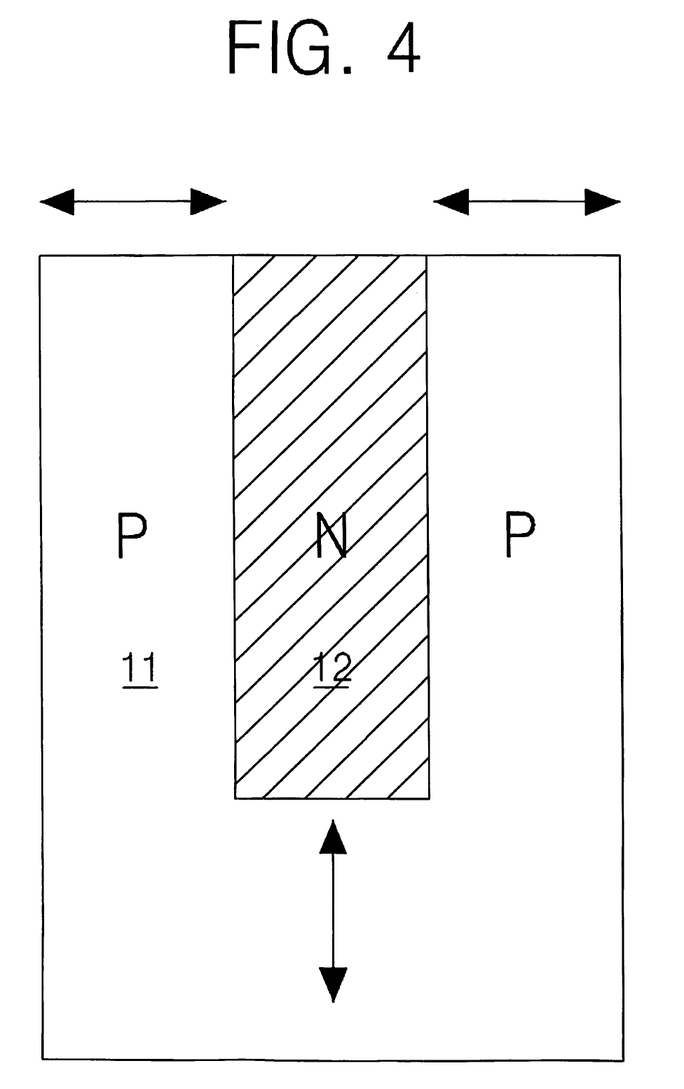

FIG. 4 illustrates a cross-section of a well illustrated in FIG. 2. Referring to FIGS. 2 and 4, the well includes the P-type well region 11 and the N-type well region 12 formed within the P-type well region 11.

Referring more specifically to FIG. 4, the depth of the N-type well region 12 and the area thereof in accordance with the depth may be adjusted within the P-type well region 11. For example, the area of the N-type well region 12 according to the depth thereof may be determined according to the amount of electrons to be drained. In more detail, the N-type well region 12 may be wider at a depth at which the amount of the electrons to be drained is relatively large, but narrower at a depth at which the amount of the electrons to be drained is relatively small.

An image sensor designer may more efficiently use a layout during design and manufacturing processes, and may control the operation characteristics of a pixel by adjusting the depth of the N-type well region 12 and the area thereof according to the depth.

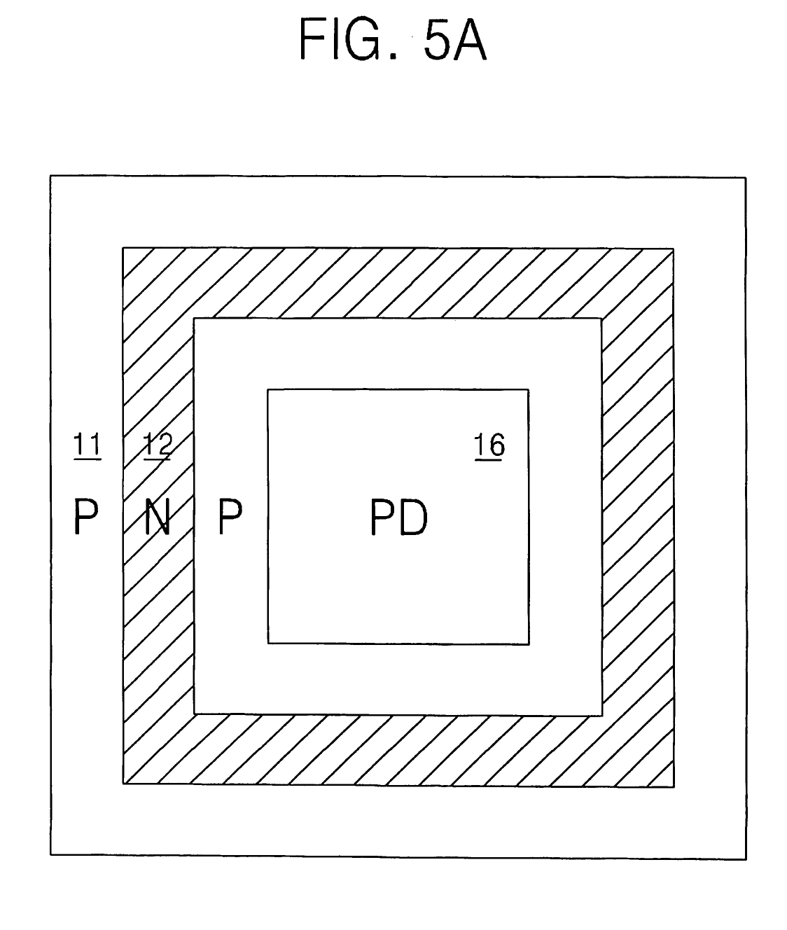

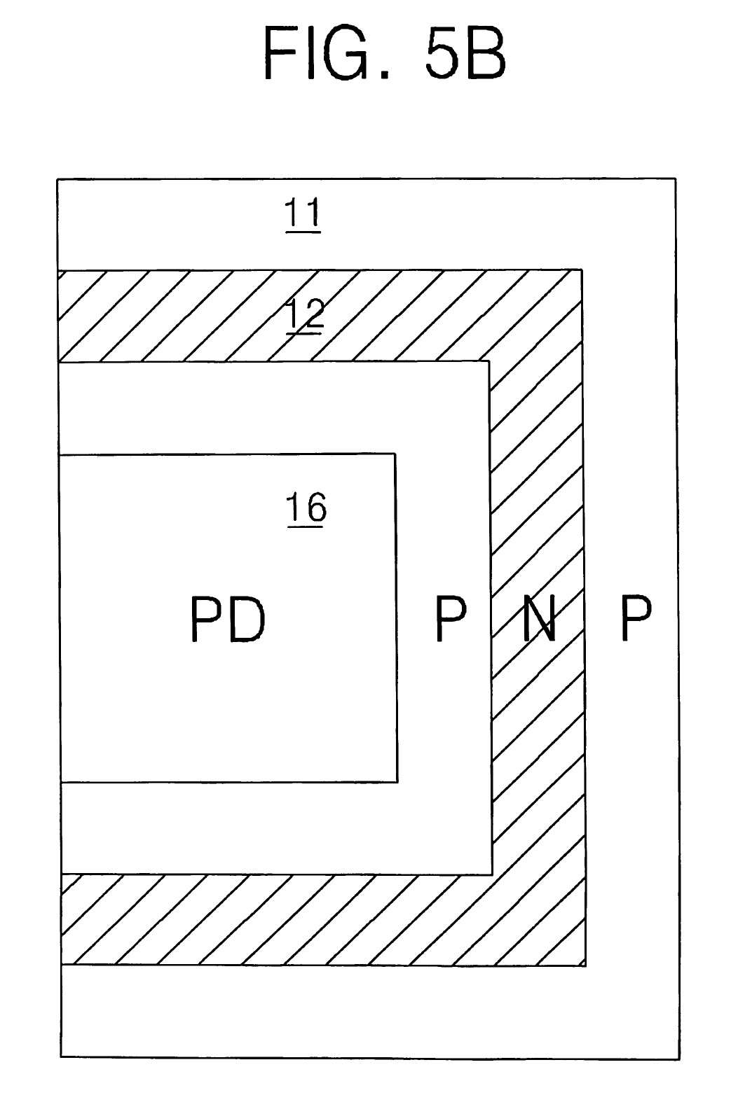

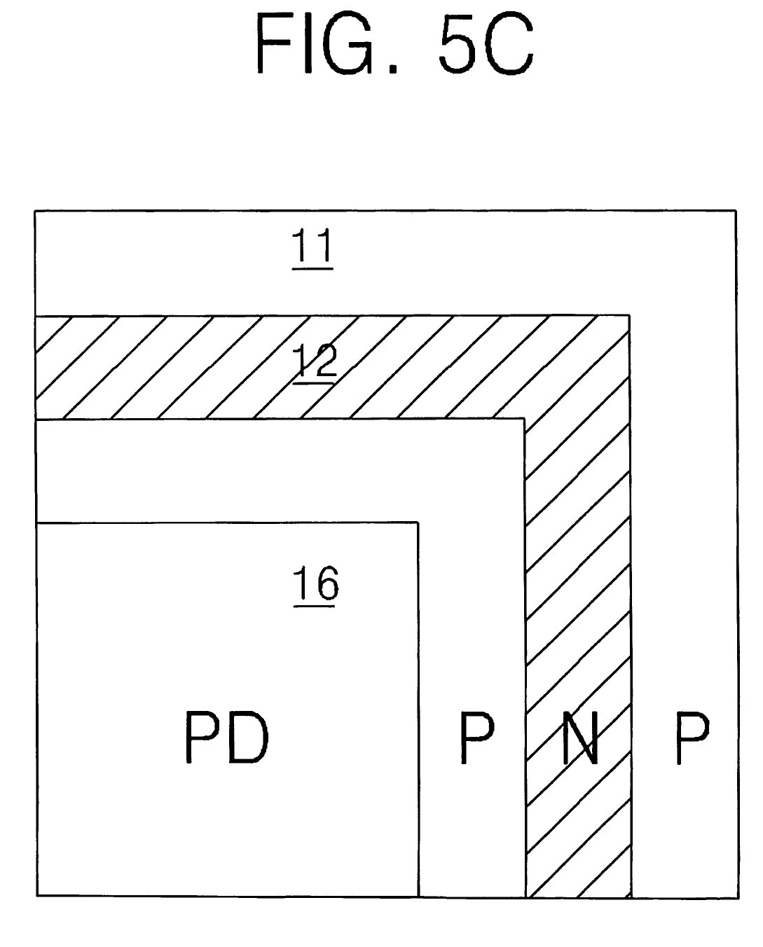

FIGS. 5A through 5C are schematic layouts of a unit pixel of the pixel array 10 included in an image sensor according to an example embodiment. In FIG. 5A, the PD 16 is surrounded on all sides for isolation by the well including the P-type well region 11 and the N-type well region 12. In FIG. 5B, the PD 16 is surrounded on three sides for isolation by the well including the P-type well region 11 and the N-type well region 12. In FIG. 5C, the PD 16 is surrounded on two sides for isolation by the well including the P-type well region 11 and the N-type well region 12.

FIGS. 5A through 5C show examples of a rectangular PD 16 and show that an isolation range by the well including the P-type well region 11 and the N-type well region 12 may be designed differently with respect to the PD 16. However, inventive concepts are not restricted to these examples.

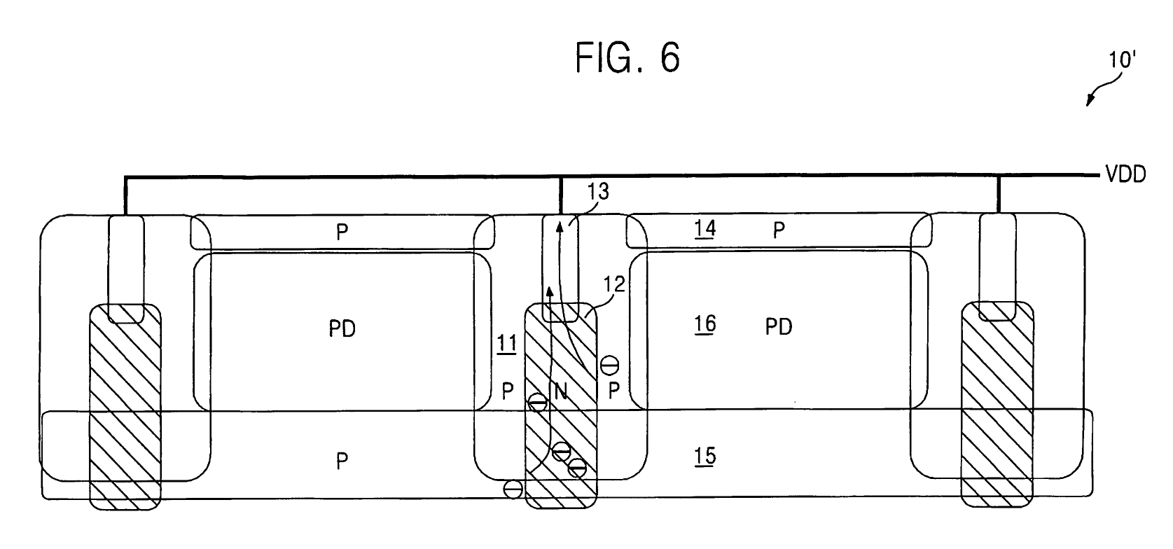

FIG. 6 is a sectional view of a pixel array included in an image sensor according to another example embodiment. The pixel array 10′ illustrated in FIG. 6 has the same or substantially the same structure as the pixel array 10 illustrated in FIG. 2, except that the pixel array 10′ does not include a STI structure (e.g., the oxide layer 17 included in the pixel array 10 illustrated in FIG. 2). A mechanism of suppressing the blooming effect and the dark current by applying a bias voltage to the N-type well region 12 may be used regardless of the presence of the STI structure.

Accordingly, as in the pixel array 10 illustrated in FIG. 2, the pixel array 10′ illustrated in FIG. 6 suppresses the blooming effect and the dark current through the N-type well region 12, thereby providing a clearer image.

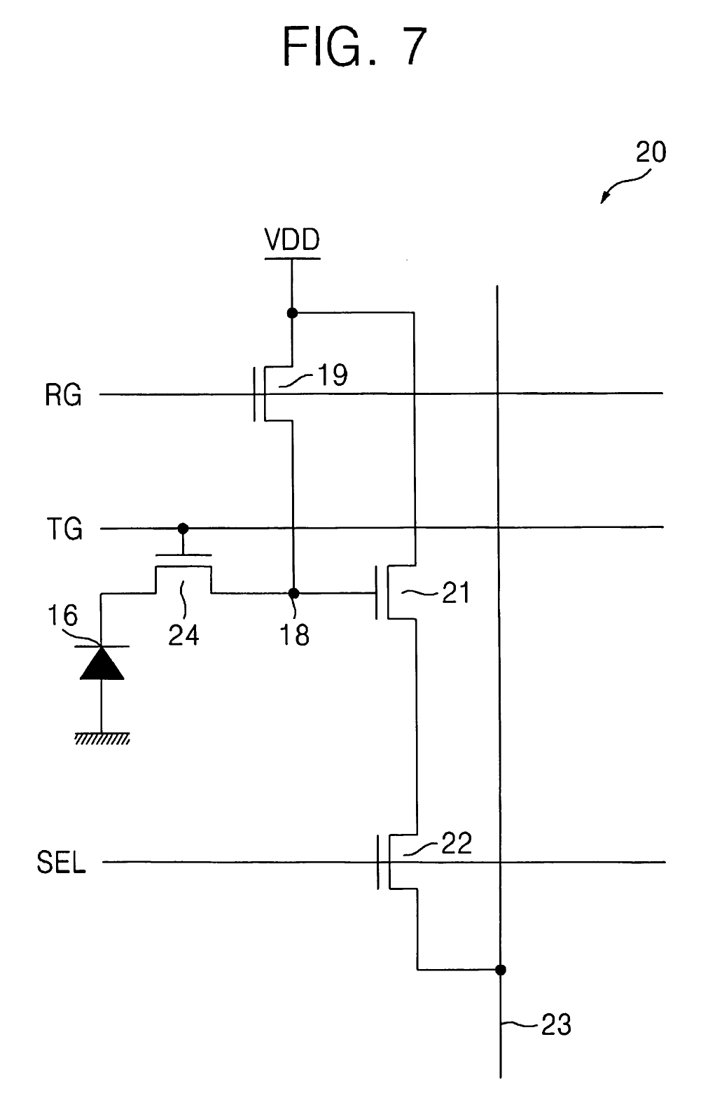

FIG. 7 is a circuit diagram of a pixel included in an image sensor according to an example embodiment. The pixel 20 shown in FIG. 7 is a four-transistor (4T) pixel. However, example embodiments are not limited thereto.

Referring to FIG. 7, the pixel 20 includes a PD 16, a floating diffusion region 18, and a plurality of transistors 19, 21, 22, and 24. The PD 16 generates photoelectrons in response to incident light. The transfer transistor 24 transmits photoelectrons from the PD 16 to the floating diffusion region 18 in response to a transfer signal TG. The reset transistor 19 resets the floating diffusion region 18 to a given, desired or predetermined voltage VDD in response to a reset signal RG.

The drive transistor 21 outputs a variable voltage through a vertical signal line 23. The variable voltage varies in response to a voltage level of the floating diffusion region 18. The select transistor 22 selects a pixel, which will output a pixel signal, in response to a selection signal SEL.

FIG. 8 is a block diagram of an image sensor according to an example embodiment.

Referring to FIG. 8, the image sensor 100 includes a photoelectric converter 110 and an image processor 130. Each of the photoelectric converter 110 and the image signal processor (ISP) 130 may be implemented in a separate chip or module.

The photoelectric converter 110 generates an image signal corresponding to a photographed subject based on incident light. The photoelectric converter 110 includes a pixel array 111, a row decoder 112, a row driver 113, a correlated double sampling (CDS) block 114, an output buffer 115, a column driver 116, a column decoder 117, a timing generator 118, a control register block 119, and a ramp generator 120.

The pixel array 111 includes a plurality of pixels arranged in a two-dimensional matrix. The plurality of pixels are connected to a plurality of row lines (not shown), respectively. The plurality of pixels are also connected to a plurality of column lines (not shown), respectively. Each of the plurality of pixels includes a red pixel, a green pixel and a blue pixel. The red pixel converts red spectrum light into an electrical signal. The green pixel converts green spectrum light into an electrical signal. The blue pixel converts blue spectrum light into an electrical signal. In addition, as illustrated in FIG. 1, a color filter for transmitting particular spectrum light is provided above each of the plurality of pixels included in the pixel array 111.

The row decoder 112 decodes a row control signal (e.g., an address signal) generated by the timing generator 118. The row driver 113 selects at least one row line from among the plurality of row lines in the pixel array 111 in response to a decoded row control signal.

The correlated double sampling (CDS) block 114 performs CDS on a pixel signal output from a pixel connected to a selected column line among the plurality of column lines in the pixel array 111. In more detail, the CDS block 114 performs CDS on a pixel signal output from a pixel connected to a selected column line in the pixel array 111, generates a sampling signal (not shown), compares the sampling signal with a ramp signal Vramp, and generates a digital signal according to a result of the comparison.

The output buffer 115 buffers and outputs digital signals output from the CDS block 114 in response to a column control signal (e.g., an address signal) output from the column driver 116.

The column driver 116 selectively activates at least one column line among the plurality of column lines in the pixel array 111 in response to a decoded control signal (e.g., an address signal) output from the column decoder 117. The column decoder 117 decodes a column control signal (e.g., an address signal) generated by the timing generator 118, and outputs the decoded control signal to the column driver 116.

The timing generator 118 generates at least one control signal for controlling the operation of at least one of the pixel array 111, the row decoder 112, the output buffer 115, the column decoder 117, and the ramp generator 120 based on a command output from the control register block 119.

The control register block 119 generates various commands for controlling the elements of the photoelectric converter 110. The ramp generator 120 outputs the ramp signal Vramp to the CDS block 114 in response to a command generated by the control register block 119. The ISP 130 generates an image based on pixel signals output from the photoelectric converter 110. The image corresponds to a photographed subject.

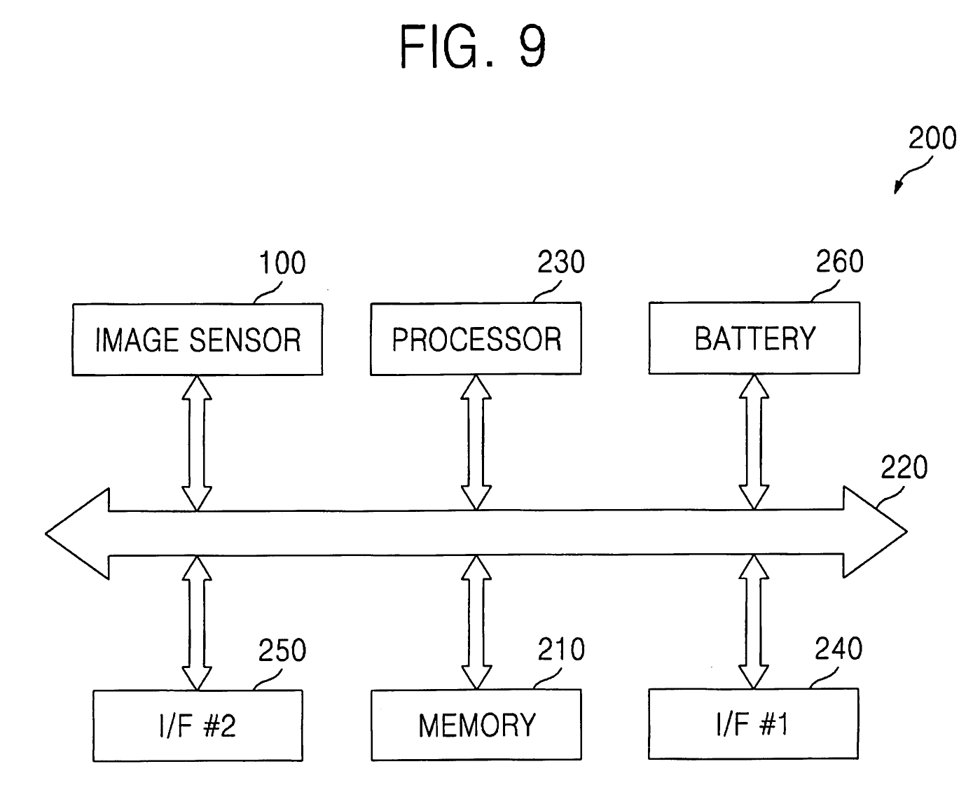

FIG. 9 is a block diagram of an electronic system including an image sensor according to an example embodiment.

Referring to FIG. 9, the electronic system 200 includes the image sensor 100, a memory 210, and a processor 230. The image sensor 100, the memory 210 and the processor 230 are connected to one another via a system bus 220. The electronic system 200 may be a digital camera, a mobile phone equipped with a digital camera, a satellite system equipped with a camera, or the like, but example embodiments are not restricted thereto.

The processor 230 generates control signals for controlling the operations of the image sensor 100 and the memory 210. The image sensor 100 generates an image corresponding to a photographed subject. The memory 210 stores the generated image.

When the electronic system 200 is embodied as a portable application or portable device, the electronic system 200 may further include a battery 260 to supply operating power to the image sensor 100, the memory 210, and/or the processor 230.

The electronic system 200 may further include a first interface 240 (e.g., an input/output unit) configured to communicate data with an external data processing device. When the electronic system 200 is a wireless system, the electronic system 200 may further include a second interface 250. In this example, the second interface 250 is a wireless interface. The wireless system may be a wireless device such as a personal digital assistant (PDA), a portable computer, a wireless telephone, a pager, a digital camera, a radio frequency identification (RFID) reader, an RFID system, etc. The wireless system may also be a wireless local area network (WLAN) system or a wireless personal area network (WPAN) system. Moreover, the wireless system may be a cellular network.

As described above, according to at least some example embodiments, an image sensor suppresses a blooming effect and a dark current that may occur between PDs, thereby providing a clearer image signal.

While some inventive concepts have been particularly shown and described with reference to example embodiments thereof, it will be understood by those of ordinary skill in the art that various changes in forms and details may be made therein without departing from the spirit and scope of inventive concepts as defined by the following claims.

What is claimed is:

1. An image sensor comprising:
a plurality of photodiodes; and
a plurality of wells configured to isolate the plurality of photodiodes from each other, each of the plurality of wells including,
a P-type well region; and
an N-type well region formed within the P-type well region.

2. The image sensor of claim 1, wherein a positive voltage is applied to the N-type well region, the positive voltage having a voltage level that varies based on an operating state of the image sensor.

3. The image sensor of claim 2, further comprising:
an oxide layer formed above each of the plurality of wells.

4. The image sensor of claim 3, wherein the oxide layer is formed within a trench.

5. The image sensor of claim 1, further comprising:
an N-type substrate electrically connected to the N-type well region.

6. The image sensor of claim 1, wherein the N-type well region has a different area according to a depth of the N-type well region.

7. The image sensor of claim 1, wherein the plurality of photodiodes are formed between a first P-type layer and a second P-type layer.

8. The image sensor of claim 7, further comprising:
an oxide layer formed above each of the plurality of wells.

9. The image sensor of claim 8, further comprising:
an N-type substrate electrically connected to the N-type well region.

10. An electronic system comprising:
the image sensor of claim 1 configured to generate an image;
a memory configured to store the generated image; and
a processor coupled to the memory and the image sensor via a bus, the processor being configured to control the image sensor and the memory.

11. The electronic system of claim 10, wherein a positive voltage is applied to the N-type well region, the positive voltage having a voltage level that varies based on an operating state of the image sensor.

12. The electronic system of claim 11, further comprising:
an oxide layer formed above each of the plurality of wells.

13. The electronic system of claim 12, wherein the oxide layer is formed within a trench.

14. The electronic system of claim 10, further comprising:
an N-type substrate electrically connected to the N-type well region.

15. The electronic system of claim 10, wherein the N-type well region has a different area according to a depth of the N-type well region.

16. The electronic system of claim 10, wherein the plurality of photodiodes are formed between a first P-type layer and a second P-type layer.

17. The electronic system of claim 16, further comprising:
an oxide layer formed above each of the plurality of wells.

18. The electronic system of claim 17, further comprising:
an N-type substrate electrically connected to the N-type well region.
